(19) United States
(12) Patent Application Publication
(10) Pub. No.: US 2017/0358766 A1
(43) Pub. Date: Dec. 14, 2017

(54) ORGANIC SEMICONDUCTOR PHOTOVOLTAIC DEVICES AND COMPOSITIONS WITH ACCEPTOR-DONOR-ACCEPTOR TYPE POLYMER ELECTRON DONORS

(71) Applicants: SolarWindow Technologies, Inc., Columbia, MD (US); ALLIANCE FOR SUSTAINABLE ENERGY, LLC, Golden, CO (US)

(72) Inventors: Scott R. Hammond, Wheat Ridge, CO (US); Ross Larsen, Boulder, CO (US); Dana Crosby Olson, Boulder, CO (US); Zbyslaw Owczarczyk, Littleton, CO (US)

(21) Appl. No.: 15/178,384

(22) Filed: Jun. 9, 2016

(51) Int. Cl. H01L 51/42; H01L 51/44; H01L 51/00

(52) U.S. Cl. CPC H01L 51/4253; H01L 51/0002; H01L 51/442; H01L 51/0043; H01L 51/0046; H01L 51/0035

(57) ABSTRACT

Organic semiconductor photovoltaic devices and compositions with acceptor-donor-acceptor type polymer electron donors are provided. In one embodiment, a composition of matter comprises a copolymer material having an acceptor-donor-acceptor moiety repeat unit.

### GOVERNMENT RIGHTS

The United States Government has rights in this invention under Contract No. DE-AC36-08GO28308 between the United States Department of Energy and the Alliance for Sustainable Energy, LLC, the manager and operator of the National Renewable Energy Laboratory.

### BACKGROUND

The state of the art in electron donors for organic photovoltaic (OPV) bulk heterojunction (BHJ) devices is the Donor-Acceptor copolymer electron donor. While early success in OPV BHJ devices was based upon the electron donor homopolymer poly (3-hexylthiophene) (P3HT), this material has a relatively large band gap (˜1.9 eV) that limits the wavelengths of light that can be absorbed, and thus limits the current the devices can produce. It was found that if the BHJ was instead fabricated with alternating copolymers consisting of a repeating sequence of an electron-rich moiety (referred to an as electron donor) and an electron poor moiety (referred to as an electron acceptor) the result was the occurrence of a so-called push-pull phenomenon within the BHJ that resulted in significantly lower band gaps as compared to a BHJ with homopolymer electron donors. Very low bandgap materials are potentially very attractive for semitransparent OPV devices for use in building-integrated photovoltaics (BIPV) applications. The limited absorption width of organic semiconductors has the potential for efficient near-infrared (IR) absorption while still allowing for high visible light transmission (VLT), unlike the case with inorganic semiconductors. In current OPV devices, utilization of Donor-Acceptor copolymers has been extremely successful as electron donors in BHJs that also utilize fullerenes for the absorber layer electron acceptor. However, there are limits in the materials properties accessible from Donor-Acceptor copolymers. In particular, it is difficult to obtain ultra-low bandgap (≦1 eV) materials using the conventional Donor-Acceptor copolymer paradigm, due to the limits of known donor and acceptor strengths, which ultimately limits the currents and open circuit voltages that can be realized from Donor-Acceptor based devices.

While small molecule OPV systems that deviate from the Donor-Acceptor copolymer paradigm exist and have been used with some success in OPV devices, they are limited to relatively moderate band gaps (for example, ˜1.5 eV) and exhibit difficulties in processing due to issues with solubility, low hole mobilities, and limited phase segregation often seen in such small molecule-based BHJ systems.

For the reasons stated above and for other reasons stated below which will become apparent to those skilled in the art upon reading and understanding the specification, there is a need in the art for systems and methods that provide organic semiconductor photovoltaic devices with acceptor-donor-acceptor type polymer electron donors.

### SUMMARY

The Embodiments of the present disclosure provide methods and systems for organic semiconductor photovoltaic devices with acceptor-donor-acceptor type polymer electron donors and will be understood by reading and studying the following specification.

Organic semiconductor photovoltaic devices and compositions with acceptor-donor-acceptor type polymer electron donors are provided. In one embodiment, a composition of matter comprises a copolymer material having an acceptor-donor-acceptor moiety repeat unit.

### DRAWINGS

Embodiments of the present disclosure can be more easily understood and further advantages and uses thereof more readily apparent, when considered in view of the description of the preferred embodiments and the following figures in which:

FIG. 1 is a diagram of an organic photovoltaic device of one embodiment of the present disclosure;

FIG. 2 is a diagram illustrating a repeat unit of an electron donor copolymer of one embodiment of the present disclosure;

FIG. 2A illustrates extrapolated estimates of HOMO and LUMO levels and shift in absorption gap for a hypothetical electron donor copolymer of one embodiment of the present disclosure;

FIG. 3 is a diagram illustrating a repeat unit of an electron donor copolymer of one embodiment of the present disclosure;

FIGS. 4A-4I are diagrams illustrating various A-D-A repeat units for electron donor copolymers of alternate embodiments of the present disclosure;

FIG. 5 is a diagram illustrating a transparent photovoltaic device of one embodiment of the present disclosure;

FIG. 6 is a diagram illustrating an organic photovoltaic device of one embodiment of the present disclosure; and

FIG. 7 is a flow chart illustrating a method of one embodiment of the present disclosure.

In accordance with common practice, the various described features are not drawn to scale but are drawn to emphasize features relevant to embodiments of the present disclosure. Reference characters denote like elements throughout figures and text.

### DETAILED DESCRIPTION

In the following detailed description, reference is made to the accompanying drawings that form a part hereof, and in which are shown specific illustrative examples in which embodiments may be practiced. These embodiments are described in sufficient detail to enable those skilled in the art to practice the described embodiments, and it is to be understood that other embodiments may be utilized and that logical, mechanical and electrical changes may be made without departing from the scope of the embodiments of the present disclosure. The following detailed description is, therefore, not to be taken in a limiting sense.

Embodiments of the present disclosure provide for organic semiconductor devices and associated compositions of matter that incorporate an Acceptor-Donor-Acceptor copolymer repeat unit paradigm in the electron donor polymer material of an organic semiconductor absorber layer, such as for example, a bulk heterojunction (BHJ) absorber layer of a photovoltaic device. As the term is used herein and in the art of polymers, a repeat unit (which is sometimes also referred to as a repeating unit) is a part of a polymer whose repetition produces the chain or backbone of the polymer through the sequential linking of the repeat units together. That is, the polymer chain of repeat units can be expressed as a molecule chain defined by -[repeat unit]ₙ- where n is greater than or equal to two. In particular with embodiments presented herein, the polymer comprises a molecule chain defined by -[Acceptor-Donor-Acceptor]ₙ- where n is greater than or equal to two. Electron donor polymer materials having an Acceptor-Donor-Acceptor copolymer repeat unit allows for increased relative acceptor strength with respect to donor strength in the electron donor material component of the BHJ by incorporating two acceptors for each donor. This architecture creates a stronger push-pull affect than can be achieved using the conventional Donor-Acceptor copolymer paradigm. The novel Acceptor-Donor-Acceptor copolymer repeat unit architecture discussed herein provides access to different absorption spectra and energy levels than attainable with a Donor-Acceptor architecture, as is shown based on computations of electronic energy levels of polymers in Table 1.

TABLE 1

| | DA copolymer | | | ADA copolymer | | |
|---|---|---|---|---|---|---|
| | | | Absorption | | | Absorption |
| Donor Identity | HOMO | LUMO | gap | HOMO | LUMO | gap |
| ProDOT | −4.26 | −2.95 | 1.06 | −4.41 | −3.16 | 0.97 |
| EDOT | −4.26 | −2.99 | 1.03 | −4.46 | −3.22 | 0.96 |
| Triazole | −4.78 | −3.01 | 1.51 | −4.54 | −3.25 | 1.10 |
| BDT | −4.63 | −3.07 | 1.32 | −4.62 | −3.32 | 1.06 |
| CPDT | −4.37 | −3.07 | 1.04 | −4.49 | −3.25 | 0.96 |
| DTS | −4.39 | −3.01 | 1.09 | −4.49 | −3.24 | 0.98 |
| Fluorene | −4.68 | −2.91 | 1.65 | −4.57 | −3.27 | 1.11 |
| Napthodithiophene | −4.54 | −2.96 | 1.27 | −4.58 | −3.32 | 1.03 |
| Benzotrithiophene | −4.44 | −3.02 | 1.14 | −4.54 | −3.25 | 1.02 |

In Table 1, the calculated electronic properties of donor-acceptor repeat unit copolymers (DA) and acceptor-donor-acceptor repeat unit copolymers (ADA) are shown with the acceptor unit being diketo-pyrrolo-pyrrole (DPP) for all polymers. Properties are reported in units of electron-Volts (eV) and are obtained by extrapolating explicit calculations on the n=1 and n=2 cases to the polymer limit as described by Larsen (See, Larsen, R. E. (2016). Simple Extrapolation Method To Predict the Electronic Structure of Conjugated Polymers from Calculations on Oligomers. J. Phys. Chem. C, 120 (18), pp 9650-9660, which is incorporated herein by reference in its entirety). The explicit calculations used density functional theory (DFT) on geometrically optimized structures to compute the HOMO and LUMO and used time-dependent DFT to compute the first excitation energy, here called the absorption gap. For all calculations the B3LYP exchange-correlation functional and a 6-31g(d) Pople-type Gaussian basis set were used.

Some embodiments of the present disclosure include organic photovoltaic (OPV) devices having a bulk heterojunction material absorber layer that includes an electron donor polymer comprising repeating sequences of an Acceptor-Donor-Acceptor copolymer repeat unit. The resulting OPV devices exhibit smaller bandgaps than previously achievable and also exhibit an enhanced responsiveness for tuning Highest Occupied Molecule Orbital (HOMO) and Lowest Unoccupied Molecule Orbital (LUMO) energy levels as well as tuning the absorption bandwidth of the absorber layer.

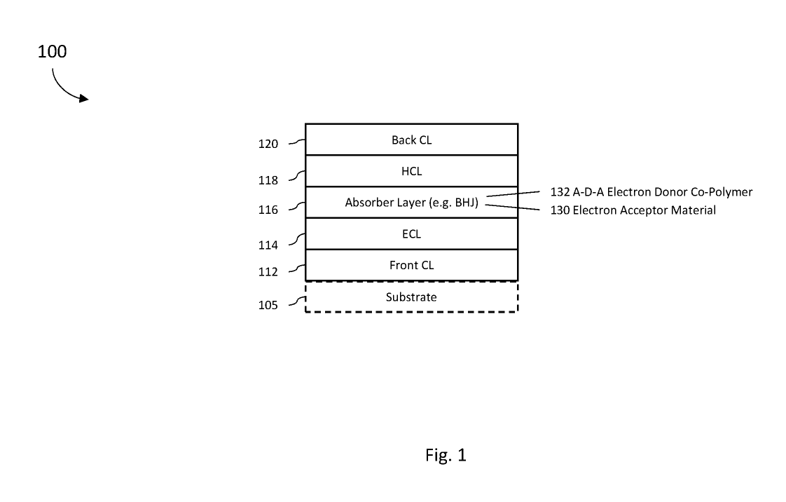

FIG. 1 is a diagram illustrating an example OPV device 100 of one embodiment of the present disclosure. As shown in FIG. 1, the layers of OPV device 100 may be deposited onto an underlying substrate layer 105. In some alternate implementations of this embodiment, the substrate layer 105 may be optionally removed such that the final OPV device 100 may, or may not, include the presence of substrate layer 105. The layers deposited onto substrate layer 105 which define OPV device 100 include a front contact layer 112, an electron collection layer (ECL) 114, an absorber layer 116, a hole collection layer (HCL) 118 and a back contact layer 120. In the particular embodiment shown in FIG. 1, absorber layer 116 operates as a photovoltaic absorber layer that generates electron and hole charges from absorbed photons, utilizing an electron donor polymer having a repeating sequence of an Acceptor-Donor-Acceptor copolymer repeat unit.

The purpose of the hole collection layer 118 is to function as a barrier to electrons attempting to migrate to the back contact layer 120 while at the same time allowing hole charges produced in the absorber layer 116 to flow into the back contact layer 120. Similarly, the purpose of the electron collection layer 114 is to function as a barrier to holes attempting to migrate to the front contact layer 112 while allowing electrons produced in the absorber layer 116 to flow from into the front contact layer 112. The resulting collection of opposing charges accumulating in the front contact layer 112 (negative electron charges) and back contact layer 120 (positive hole charges) manifests a voltage potential across the OPV device 100. As would be appreciated by one of ordinary skill in the art of photovoltaics, at least one of either front contact layer 112 or the back contact layer 120 are transparent to a spectrum of photons that falls within the absorption band of the absorber layer 116 in order for such photons to reach the absorber layer 116 for the photovoltaic effect to occur. In some embodiments, device 100 is at least semitransparent to the visible light spectrum meaning that at least some light visible to human beings (generally considered to be light in the wavelength range of approximately 380 nm to 680 nm) completely penetrates through OPV device 100 without being absorbed. In such embodiments, both the front contact layer 112 and back contact layer 120 are transparent contact layers (TCLs). In some implementations, a TCL may comprise a transparent conducting oxide (TCO), transparent film or other material.

For embodiments where visible light transparency of OPV device 100 is not desired or otherwise not of concern, a metallization layer of silver or other opaque conducting material may be used to form one of the contact layers 112, 120. In one embodiment, hole collection layer 118 comprises a thin film layer of a doped conjugated polymer such as, but not limited to PEDOT:PSS (poly(3,4-ethylenedioxythiophene):poly(styrenesulfonate)). In at least one such embodiment where the hole collection layer 118 comprises PEDOT:PSS, the same layer may also serve as the transparent back contact layer 120. The electron collection layer 114 may comprise a transparent oxide such as but not limited to zinc oxide (ZnO) or a titanium dioxide (TiO₂). In other embodiments, other materials for hole collection layer 110, election conduction layer 114, front contact layer 112 and/or back contact layer 120 known to those of ordinary skill in the art for such uses may be utilized.

As mentioned above, in accordance with one embodiment of the present disclosure, the absorber layer 116 may comprise an electron acceptor material 130 and a copolymer electron donor material 132 that are blended into a bulk composite of the two materials to form a bulk-heterojunction (BHJ). The electron acceptor material 130 may comprise for example, fullerene or a fullerene derivative, or alternately a polymer or small molecule material known to those of skill in the art. The electron donor copolymer material 132 incorporates a repeat unit having an Acceptor-Donor-Acceptor pattern of co-polymerized monomers. That is, in the polymer chain of the copolymer electron donor material 132 there exists a repeating sequence of a repeat unit that comprises two acceptor moieties arranged on either side of a donor moiety. The Acceptor-Donor-Acceptor repeat unit results in a novel electrical structure within the copolymer material 132 in which two acceptor moieties are located adjacent to each other in the polymer sequence where repeat units are linked in sequence. It should be noted however that embodiments comprising a bilayer organic absorber layer 116 having the acceptor material 130 and donor material 132 as distinct layers are also contemplated as falling within the scope of embodiments of the present disclosure.

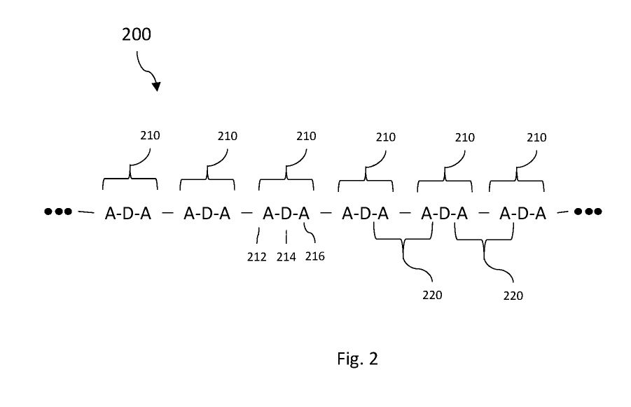

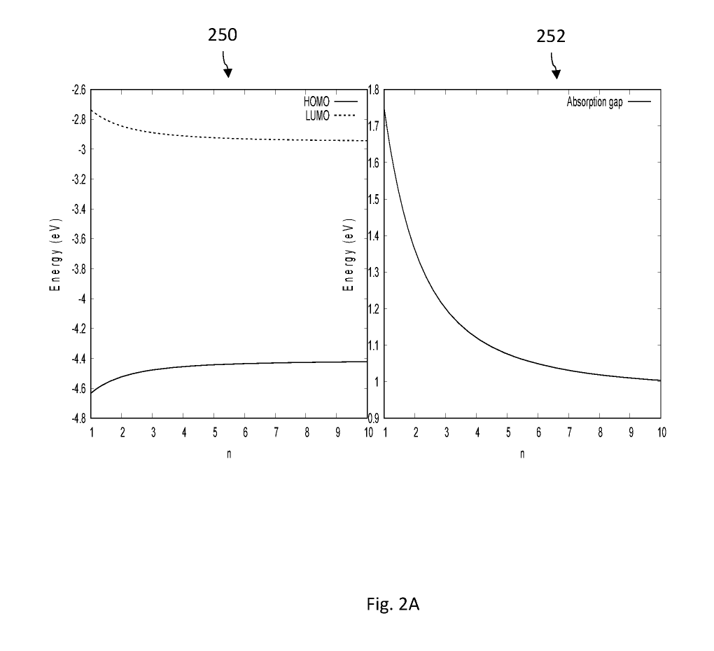

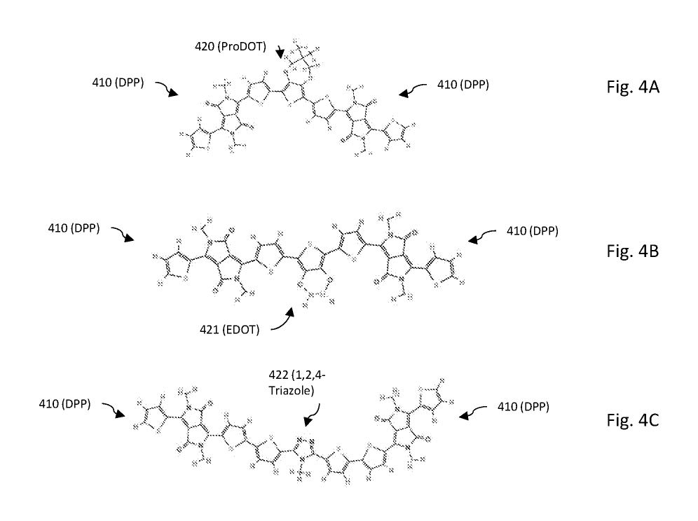

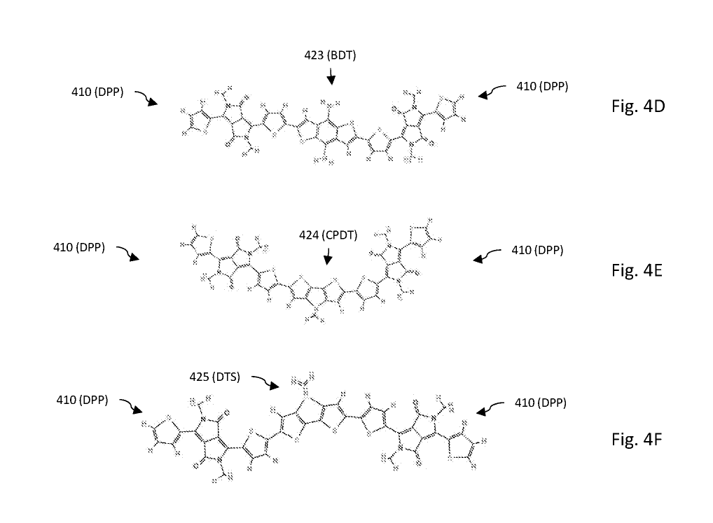

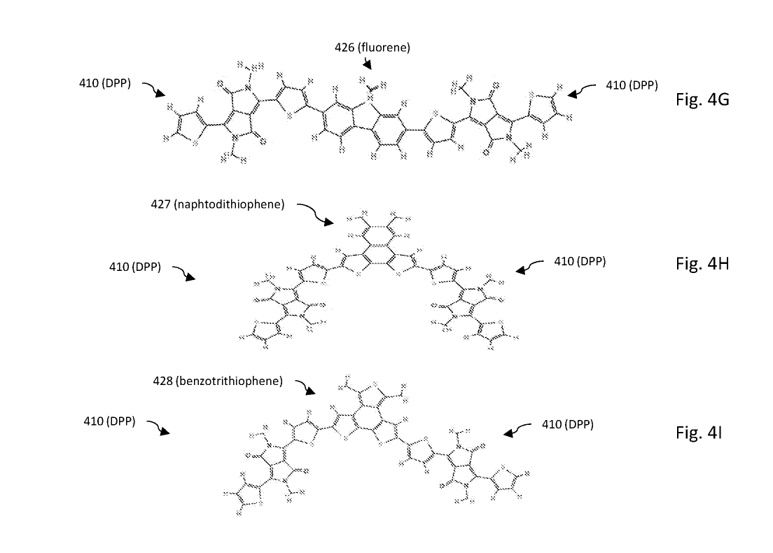

For example, FIG. 2 illustrates at 200 a sequence of Acceptor-Donor-Acceptor repeat units 210 for an example electron donor copolymer material 132 of one embodiment of the present disclosure. The Acceptor-Donor-Acceptor repeat units 210 for this polymer chain each have a sequence that includes a first acceptor moiety 212, bonded to a donor moiety 214, which in turn is bonded to a second acceptor moiety 216. As evident from FIG. 2, when such Acceptor-Donor-Acceptor repeat units 210 are synthesized together into a polymer molecule, neighboring repeat units 210 are linked together by adjacent acceptor moieties such as shown at 220. That is, the neighboring Acceptor-Donor-Acceptor repeat units 210 result in a polymer chain that includes a doubling of acceptors on either side of the donor (i.e., . . . A-A-D-A-A . . . ) which is distinct from what is found in prior small molecule or polymer OPV systems. As such, it should be noted that the polymer chain in FIG. 2 may also be alternately described as a sequence of Acceptor-Acceptor-Donor (AAD) or Donor-Acceptor-Acceptor (DAA) repeat units, both of which would refer to the same structure as an Acceptor-Donor-Acceptor (ADA) repeat unit. This structure of adjacent acceptor moieties results in a lower electron density within the copolymer material 132 component of the absorber layer 116 than previously achievable through Donor-Acceptor copolymer chains and therefore results in lower bandgaps within in the absorber layer 120. The degree of polymerization (that is, the number of repeat units (n)) comprised by the material of the example electron donor copolymer will have a direct effect on the bandgap and viscosity of the resulting absorber layer. As the number of repeat units in the polymer chain increases, the bandgap narrows and the viscosity increases. Conversely, as the number of repeat units in the polymer chain decreases, the bandgap widens and the viscosity decreases. This is illustrated in FIG. 2A, which shows for an acceptor-donor-acceptor repeat unit copolymer of a DPP moiety and a ProDOT moiety (such as shown in FIG. 4A) the expected shift in HOMO and LUMO levels (shown at 250) and the shift in absorption gap (shown at 252) as a function of the number of repeat units, based on an extrapolation procedure that utilizes explicit calculations or measurements for n=1 and n=2 to predict these properties as a function of n. Such as the previously mentioned extrapolation procedure described by Larsen (2016). For the acceptor-donor-acceptor repeat unit copolymer illustrated by FIG. 2A, extrapolation predicts that that 90% of the total gap shift (going from n=1 to infinity) may be complete by n˜6, and 99% of the total gap shift may be complete by n˜21.

Although synthesizing semiconductor polymers having Acceptor-Donor-Acceptor repeat units 210 can be slightly more complex than synthesizing Donor-Acceptor repeat units, it should be appreciated that synthesizing Acceptor-Donor-Acceptor polymer chains having a desired repeat unit is within the skill of one of ordinary skill in the art who has studied this disclosure. The particular donor and acceptor moieties combined to synthesize electron donor copolymer material 132 can be selected from a wide range of different moieties. Although it is generally well established whether specific moieties are considered electron donors or electron acceptors, it should also be noted that some moieties may function as either a donor or acceptor depending on the relative electron density of the moiety it is paired with.

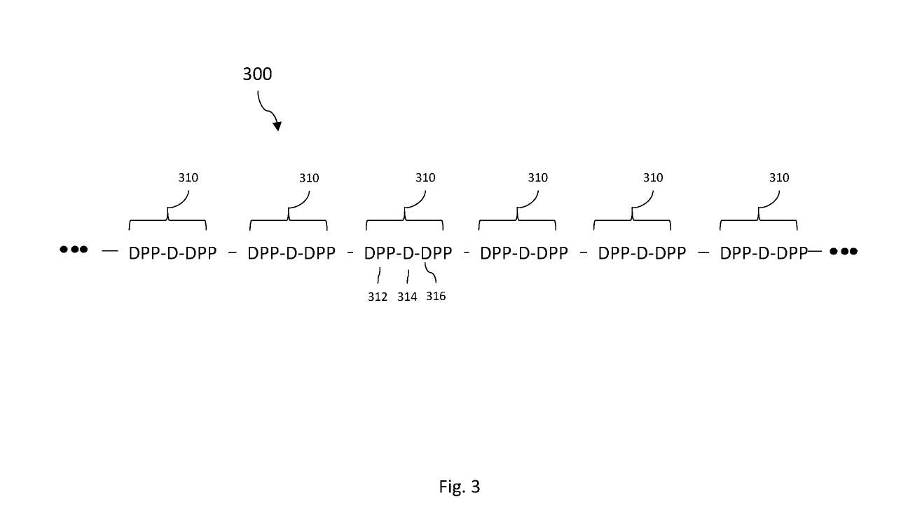

FIG. 3 illustrates at 300 an example of one general class of an electron donor copolymer material 132 that incorporates an Acceptor-Donor-Acceptor repeat unit 210 such as introduced by FIG. 2. In the particular embodiment of FIG. 3, the repeat units 310 of electron donor copolymer material 132 may comprise a donor moiety 314 selected from a range of known donor moieties, but specifically utilizes the acceptor moiety diketo-pyrrolo-pyrrole (DPP) for the first and second acceptor moieties 312 and 316. Although DPP is a known ingredient for various industrial processes (for example, in making highly saturated color paints), the embodiment illustrated in FIG. 3 discloses a novel application by incorporating the monomer as an electron acceptor moiety in electron donor copolymer material 300 having an Acceptor-Donor-Acceptor repeat unit 310. The resulting electron donor copolymer material 300 may be expected to possess excellent stability, good solubility, and to have a strong tendency to aggregate leading to exceptional hole mobility.

Further an absorber layer 116 incorporating a DPP-Donor-DPP repeat unit electron donor copolymer material 132 may be expected to exhibit very desirable band gaps and energy levels for producing devices that have a significant percentage of photon absorption occurring outside of the visible light spectrum range. Such an absorber layer may therefore provide a desirable Visible Light Transmission (VLT) percentage for applications where transparency of the resulting device is desirable (such as window or natural lighting applications, for example). For example, through the appropriate selection of the donor moiety 314, HOMO and LUMO energy levels and bandgaps may be adjusted with the objective to push the optical absorption band of the absorber layer 116 out to infrared (IR) or near IR frequencies.

In addition, embodiment incorporating DPP-Donor-DPP polymer systems may exhibit improved properties as compared to conventional Donor-DPP polymer systems, as the increased density of DPP moieties along the backbone of the polymer molecule increases the aggregation and consequent high hole mobilities, while retaining excellent solubility. This is in addition to the ability to access lower band gaps than with conventional Donor-DPP systems.

In alternate implementations, the donor moiety 314 of the Acceptor-Donor-Acceptor repeat unit 310 can include of any of a number of structures, including but not limited to: ethylenedioxythiophene (EDOT), propylenedioxythiophene (ProDOT) and derivatives thereof, benzodithiophene (BDT) derivatives, dithieneopyrrole (DTP) derivatives, dithienosilole (DTS) derivatives, cyclopentadithiophene (CPDT) derivatives, carbazole derivatives, benzotrithiophene, naphtodithiophene, and fluorene derivatives.

FIGS. 4A-4I illustrate example acceptor-donor-acceptor repeat units that may be used in conjunction with any of the embodiments presented in the present disclosure. It should be appreciated by one skilled in the art that while the examples shown exhibit methyl substituents off of the constituent moieties, the substituents could consist of any of a number of different side-chains of different lengths and chemical composition. FIG. 4A illustrates an Acceptor-Donor-Acceptor repeat unit comprising DPP acceptor moieties (shown at 410) and a ProDOT donor moiety (shown at 420). FIG. 4B illustrates an Acceptor-Donor-Acceptor repeat unit comprising DPP acceptor moieties (shown at 410) and an EDOT donor moiety (shown at 421). FIG. 4C illustrates an Acceptor-Donor-Acceptor repeat unit comprising DPP acceptor moieties (shown at 410) and a Triazole donor moiety (shown at 422). FIG. 4D illustrates an Acceptor-Donor-Acceptor repeat unit comprising DPP acceptor moieties (shown at 410) and a BDT donor moiety (shown at 423). FIG. 4E illustrates an Acceptor-Donor-Acceptor repeat unit comprising DPP acceptor moieties (shown at 410) and a CPDT donor moiety (shown at 424). FIG. 4F illustrates an Acceptor-Donor-Acceptor repeat unit comprising DPP acceptor moieties (shown at 410) and a DTS donor moiety (shown at 425). FIG. 4G illustrates an Acceptor-Donor-Acceptor repeat unit comprising DPP acceptor moieties (shown at 410) and a fluorene donor moiety (shown at 426). FIG. 4H illustrates an Acceptor-Donor-Acceptor repeat unit comprising DPP acceptor moieties (shown at 410) and a naphtodithiophene donor moiety (shown at 427). FIG. 4I illustrates an Acceptor-Donor-Acceptor repeat unit comprising DPP acceptor moieties (shown at 410) and a benzotrithiophene donor moiety (shown at 428).

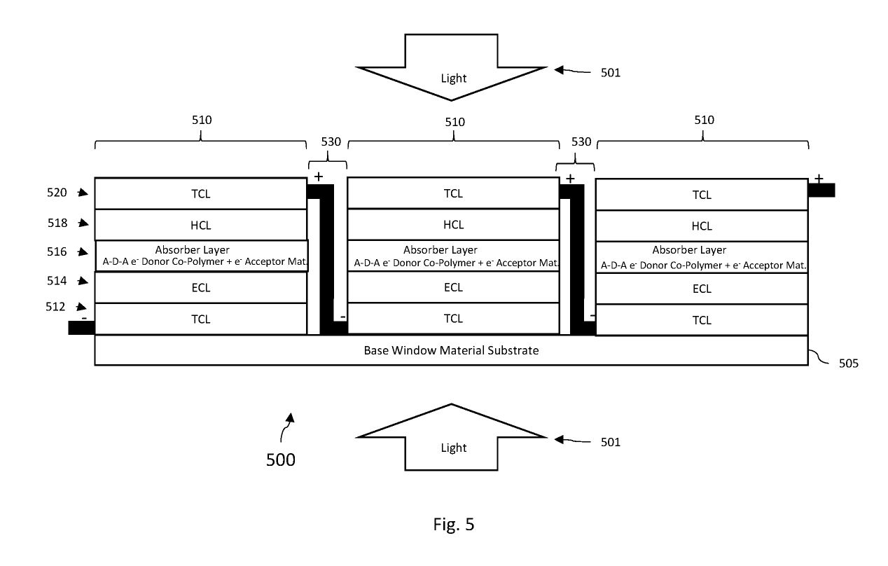

FIG. 5 is a diagram illustrating an example OPV window 500 embodiment of the present disclosure. In alternate implementations, OPV window 500 comprises part of a window unit used, for example in a building-integrated photovoltaics application that allows natural lighting into an interior space of a building. In other implementations, OPV window 500 comprises a window used for a vehicle. In still other implementations, OPV window 500 comprises part of a display screen or other transparent component of an electronics device.

OPV window 500 comprises a plurality of OPV cells 510 fabricated on a base window material substrate 505. In alternate implementations, base window material substrate 505 may comprise a rigid semi-transparent material such as a glass window pane or a sheet of acrylic or acrylic glass, semi-transparent plastic or film material. Each of the OPV cells 510 include the same structure and operate as described above with respect to OPV device 100. In particular, the OPV cells 510 include front and back contact layers 512 and 520 (both of which are realized as transparent contact layers), a hole collection layer 518, an organic semiconductor absorber layer 516 and an electron collection layer 514. In one implementation, the absorber layer 516 is a BHJ absorber layer that comprises an electron acceptor material blended with an electron donor polymer having an Acceptor-Donor-Acceptor copolymer repeat unit. As such, any of the alternate compositions applicable to the Acceptor-Donor-Acceptor copolymer repeat unit 210 of the electron donor copolymer 132 described herein are applicable to the electron donor copolymer material of absorber layer 516. The electron acceptor material of absorber layer 516 may comprise for example, fullerene or a fullerene derivative, or alternately a polymer or small molecule material known to those of skill in the art, such as described for electron acceptor material 130 of OPV device 100 above. Each of the OPV cells 510 are electrically coupled by electrical interconnects 530. The electrical interconnects 530 may provide for series interconnection of the OPV cells 510 (as illustrated in FIG. 5) or alternately parallel interconnection of the OPV cells 510. In one embodiment, the various device layers of the OPV cells 510 are deposited across the base window material substrate 505 and scribes are cut at least partially into the layers to form the electrically distinct OPV cells 510. Subsequent layers of material may then be deposited to create the electrical interconnects 530 between the OPV cells 510.

It should be appreciated that the designation of “front” and “back” with respect to the OPV cells 510 and contact layers 520, 512 is essentially arbitrary as light may enter the OPV cells 510 from either side to produce electricity. In non-transparent OPV devices, the top contact layer, 120, is opaque and often reflective so as to reflect light back into the BHJ layer. By convention, light is expected to enter or exit the device from the opposing “front” side, which makes the substrate and adjacent contact layer the “front” side. As such, as the terms are used herein, the “front” side of an OPV device refers to layers between the BHJ layer and the substrate on which the layers were deposited, while the “back” side of an OPV device refers to those layers on the opposite side of the BHJ layer from the substrate, regardless as to whether or not the OPV device is semi-transparent.

In the embodiment of FIG. 5, when light 501 enters into the OPV cells 510 the absorber layers 516 generate electron and hole charges from absorbed photons. The positive and negative electrical charges are collection in the respective contact layers 520 and 512 and through the electrical interconnects 530 (which may couple the respective contact layers 520 and 512 in either a serial or parallel configuration) bring the charges to positive and negative electrodes 540 and 542 (which may be positioned, for example, at the edges of OPV window 500). The positive and negative electrodes 540 and 542 may in turn be coupled to one or more electronic devices in order to provide electrical power to the devices, and/or for storage of the energy generated by OPV window 500.

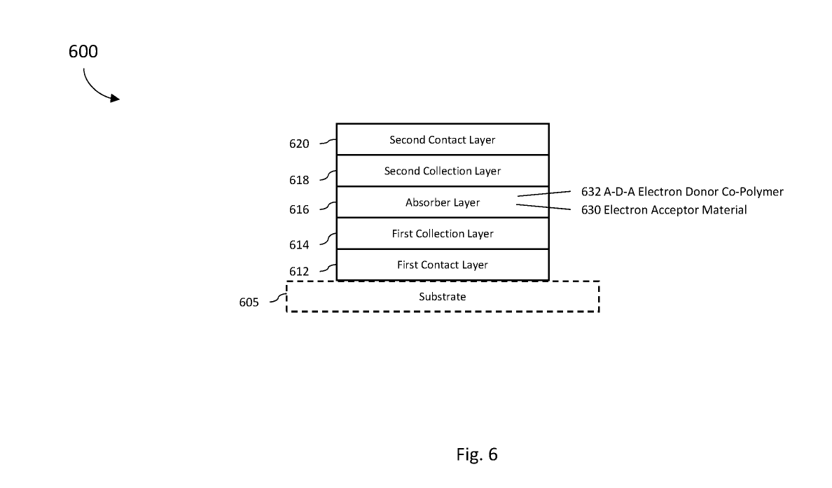

FIG. 6 is a diagram of a general organic photovoltaic device 600 of one embodiment of the present disclosure. In some implementations, organic semiconductor device 600 may comprise an OPV device such as OPV device 100 or OPV window 500. As shown in FIG. 6, the layers of organic semiconductor device 600 may be deposited onto an underlying substrate layer 605. In some alternate implementations of this embodiment, the substrate layer 605 may be optionally removed such that the final organic semiconductor device 600 may, or may not, include the presence of substrate layer 605. The layers deposited onto substrate layer 605 which define organic semiconductor device 600 include a first contact layer 612, a first charge collection layer 614 (which may include either a hole collection layer (HCL) or an electron collection layer (ECL)), an absorber layer 616, a second charge transport layer 618 (which may include either an electron collection layer (ECL) or a hole collection layer (HCL)), and a second contact layer 120. It should be appreciated that when the first charge collection layer 614 comprises an HCL, then the second charge collection layer 618 comprises an ECL. Similarly, when the first charge collection layer 614 comprises an ECL, then the second charge collection layer 618 comprises an HCL. The second contact layer 620 may be implemented as a transparent contact layer to allow photons to either enter or exit device 600. Where organic semiconductor device 600 is intended to be a semi-transparent device, then both the first and second contact layers 612, 620 are implemented as transparent contact layers to allow photons to either enter or exit device 600.

In accordance with the present disclosure, the absorber layer 616 comprises an electron acceptor material 630 and a copolymer electron donor material 632. In some embodiments, the acceptor material 630 and donor material 632 are blended into a bulk composite of the two materials to form a bulk-heterojunction (BHJ). In other embodiments, the absorber layer 616 comprises a bilayer organic absorber layer having the acceptor material 630 and donor material 632 as distinct layers. The electron acceptor material 630 may comprise for example, fullerene or a fullerene derivative, or alternately a polymer or small molecule material known to those of skill in the art.

The electron donor copolymer material 632 incorporates a repeat unit having an Acceptor-Donor-Acceptor pattern of co-polymerized monomers. In the polymer chain of the copolymer electron donor material 632 there exists a repeating sequence of a repeat unit that comprises two acceptor moieties arranged on either side of a donor moiety. The Acceptor-Donor-Acceptor repeat unit results in a novel electrical structure within the copolymer material 632 in which two acceptor moieties are located adjacent to each other in the polymer sequence where repeat units are linked in sequence. Because the electron donor copolymer material 632 incorporates the Acceptor-Donor-Acceptor repeat unit pattern as the Acceptor-Donor-Acceptor repeat unit 210 introduced by FIG. 2, any of the alternate compositions applicable to the Acceptor-Donor-Acceptor copolymer repeat unit 210 of the electron donor copolymer 132 described previously herein are applicable to the electron donor copolymer material of absorber layer 616. In some embodiments, a plurality of organic semiconductor devices 600 may be coupled together in either series or parallel configurations such as through electrical interconnects in the manner shown in FIG. 5.

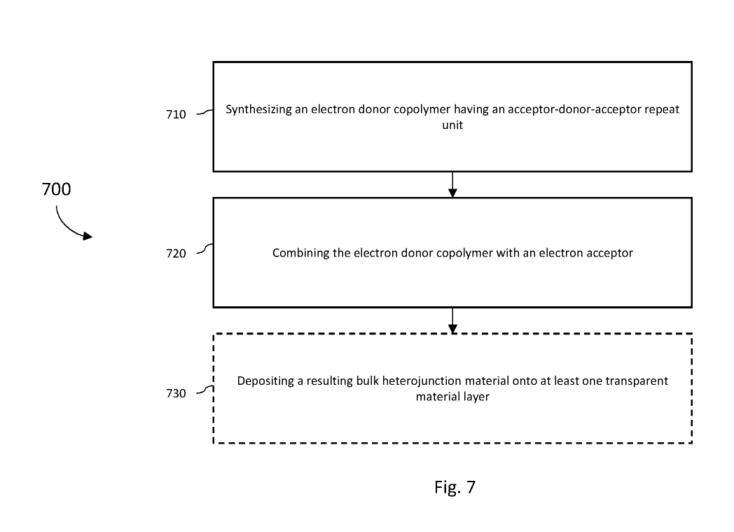

FIG. 7 is a flow chart illustrating a method 700 of one embodiment of the present disclosure. It should be understood that method 700 may be implemented in conjunction with any of the embodiments described above with respect to FIGS. 1, 2, 3, 4A-4I, 5 and 6. As such, elements of method 700 may be used in conjunction with, in combination with, or substituted for elements of those embodiments described above. Further, the functions, structures and other description of elements for such embodiments described above may apply to like named elements of method 700 and vice versa.

The method begins at 700 with synthesizing an electron donor copolymer having an acceptor-donor-acceptor repeat unit. That is, the electron donor copolymer comprises a repeating unit of co-polymerized monomers that incorporate an acceptor-donor-acceptor moiety pattern. This acceptor-donor-acceptor moiety pattern is illustrated by the Acceptor-Donor-Acceptor repeat units 210 of FIG. 2. The Acceptor-Donor-Acceptor repeat units 210 each have a sequence that includes a first acceptor moiety 212, bonded to a donor moiety 214, which in turn is bonded to a second acceptor moiety 216. When such Acceptor-Donor-Acceptor repeat units are synthesized together into a polymer molecule, neighboring repeat units are linked together by adjacent acceptor moieties. This structure of adjacent acceptor moieties results in a lower electron density within the electron donor copolymer than previously achievable through Donor-Acceptor copolymer chains. It should be appreciated that synthesizing Acceptor-Donor-Acceptor polymer chains as a desired repeat unit is within the skill of one of ordinary skill in the art who has studied this disclosure. For example, in one embodiment, synthesizing Acceptor-Donor-Acceptor polymer chains may be accomplished by the homopolymerization of individual Acceptor-Donor-Acceptor monomers to form the chain of Acceptor-Donor-Acceptor repeat units. In another embodiment, synthesizing Acceptor-Donor-Acceptor polymer chains may be accomplished by co-polymerization of an Acceptor-Acceptor monomer with a Donor monomer to produce an Acceptor-Donor-Acceptor repeat unit copolymer.

The particular donor and acceptor moieties combined to synthesize the electron donor copolymer can be selected from a wide range of different moieties. Although it is generally well established whether specific moieties are considered electron donors or electron acceptors, it should also be noted that some moieties may function as either a donor or acceptor depending on the relative electron density of the moiety it is paired with.

One general class of an electron donor copolymer that may be synthesized at 710 is shown at 300 in FIG. 3. This particular electron donor copolymer material 300 incorporates an Acceptor-Donor-Acceptor repeat unit 310 comprises a donor moiety 314 selected from a range of known donor moieties, but specifically utilizes the acceptor moiety diketo-pyrrolo-pyrrole (DPP) for the first and second acceptor moieties 312 and 316. Although DPP is a known ingredient for various industrial processes (for example, in making highly saturated color paints), applying DPP as part of synthesizing an electron donor copolymer having an acceptor-donor-acceptor repeat unit discloses a novel application. The resulting electron donor copolymer material 300 possesses excellent stability, good solubility, and a strong tendency to aggregate leading to exceptional hole mobility.

The method proceeds to 720 with combining the electron donor copolymer with an electron acceptor. In one embodiment, the electron donor copolymer is combined with an electron acceptor by layering one material on top of the other to produce a bilayer organic material layer. In other embodiments, the electron donor copolymer is combined with an electron acceptor by blending the electron donor copolymer with an electron acceptor into a bulk heterojunction material. The electron acceptor material may comprise for example, fullerene or a fullerene derivative, or alternately a polymer or small molecule material known to those of skill in the art. The formation of a bulk heterojunction material may be used to form an absorber layer of an OPV device that generates electron and hole charges from absorbed photons. A bilayer structure may alternately be used to form an absorber layer of an OPV device. Organic semiconductor devices incorporating the resulting bulk heterojunction material exhibit smaller bandgaps than previously achievable from donor-acceptor polymer architectures and also exhibit an enhanced responsiveness for tuning Highest Occupied Molecule Orbital (HOMO) and Lowest Unoccupied Molecule Orbital (LUMO) energy levels as well as tuning the absorption band width of the absorber layer.

In some embodiments, a bulk heterojunction material produced from steps 710 and 720 may be used to fabricate an absorber layer of a semi-transparent organic semiconductor device, such as but not limited to OPV window 500 described above. In that case, the bulk heterojunction material at 730 is deposited on a transparent material layer. For example, in producing a transparent device such as in FIG. 5, the bulk heterojunction material may be applied onto the transparent material of a transparent electron collection layer 514, which itself was deposited on a transparent contact layer 512 and transparent substrate 505. Subsequent device layers may then be deposited on the bulk heterojunction material and, electrical interconnects optionally fabricated, to complete the particular structure of the desired device, such as any illustrated or discussed with respect to the above figures.

### Example Embodiments

Example 1 includes a composition of matter, the composition of matter comprising a copolymer material having an acceptor-donor-acceptor moiety repeat unit.

Example 2 includes the composition of matter of example 1, wherein: the acceptor moieties of the acceptor-donor-acceptor moiety repeat unit comprise a diketo-pyrrolo-pyrrole (DPP) monomer.

Example 3 includes the composition of matter of example 2, wherein the donor moiety of the acceptor-donor-acceptor moiety repeat unit comprises one of a group of monomers comprising: ethylenedioxythiophene (EDOT) and EDOT derivatives; propylenedioxythiophene (ProDOT) and ProDOT derivatives; benzodithiophene (BDT) and BDT derivatives; dithieneopyrrole (DTP) and DTP derivatives; dithieneosilole (DTS) and DTS derivatives; cyclopentadithiophene (CPDT) and CPDT derivatives; carbazole and carbazole derivatives; benzotrithiophene and benzotrithiophene derivatives; naphtodithiophene and naphtodithiophene derivatives; and fluorene and fluorene derivatives.

Example 4 includes the composition of matter of any of examples 1-3, wherein the copolymer material is further blended with an electron acceptor material into a bulk composite to form a bulk heterojunction material, wherein the copolymer material defines an electron donor material within the bulk heterojunction material.

Example 5 includes the composition of matter of example 4, wherein the electron acceptor material comprise one of a group of electron acceptor materials comprising: fullerene; a fullerene derivative; a polymer; and a small molecule material.

Example 6 includes an organic photovoltaic device, the device comprising: an organic semiconductor layer comprising a combination of an electron acceptor material with an electron donor copolymer material; wherein the electron donor copolymer material comprises a repeating sequence of a repeat unit having an acceptor-donor-acceptor moiety pattern.

Example 7 includes the device of example 6, wherein the organic semiconductor layer comprises a blend of the electron acceptor material with the electron donor copolymer material forming a bulk heterojunction.

Example 8 includes the device of example 6, wherein the organic semiconductor layer comprises a layering of the electron acceptor material and the electron donor copolymer material.

Example 9 includes the device of any of examples 6-8, wherein: the repeat unit acceptor moieties each comprise a diketo-pyrrolo-pyrrole (DPP) monomer.

Example 10 includes the device of examples 6-9, wherein the repeat unit donor moiety comprises one of a group of monomers comprising: ethylenedioxythiophene (EDOT) and EDOT derivatives; propylenedioxythiophene (ProDOT) and ProDOT derivatives; benzodithiophene (BDT) and BDT derivatives; dithieneopyrrole (DTP) and DTP derivatives; dithieneosilole (DTS) and DTS derivatives; cyclopentadithiophene (CPDT) and CPDT derivatives; carbazole and carbazole derivatives; benzotrithiophene and benzotrithiophene derivatives; naphtodithiophene and naphtodithiophene derivatives, and fluorene and fluorene derivatives.

Example 11 includes the device of any of examples 6-10, wherein the electron acceptor material comprise one of a group of electron acceptor materials comprising: fullerene; a fullerene derivative; a polymer; and a small molecule material.

Example 12 includes the device of any of examples 6-11, further comprising: a first contact layer; a second contact layer; a hole collection layer; an electron collection layer; and an absorber layer that comprises the bulk heterojunction layer, the absorber layer positioned between the hole collection layer and the electron collection layer.

Example 13 includes an organic photovoltaic device, the device comprising: a first contact layer; a second contact layer; a hole collection layer adjacent to the first transparent contact layer; an electron collection layer adjacent to the second transparent contact layer; and an absorber layer positioned between the hole collection layer and the electron collection layer, the absorber layer comprising an electron acceptor material and an electron acceptor polymer material, wherein the electron acceptor polymer material has an acceptor-donor-acceptor repeat unit.

Example 14 includes the device of examples 13, wherein at least one of the first contact layer or the second contact layer comprises a transparent contact layer.

Example 15 includes the device of any of examples 13-14, wherein both the first contact layer and the second contact layer comprises a transparent conducting layer; and wherein the absorber layer is at least semi-transparent to light having a wavelength in the visible light spectrum.

Example 16 includes the device of any of examples 13-15, wherein: the acceptor-donor-acceptor repeat unit comprises a diketo-pyrrolo-pyrrole (DPP) monomer acceptor moiety,

Example 17 includes the device of any of examples 13-16, wherein a donor moiety of the acceptor-donor-acceptor repeat unit comprises one of a group of monomers comprising: ethylenedioxythiophene (EDOT) and EDOT derivatives; propylenedioxythiophene (ProDOT) and ProDOT derivatives; benzodithiophene (BDT) and BDT derivatives; dithieneopyrrole (DTP) and DTP derivatives; dithieneosilole (DTS) and DTS derivatives; cyclopentadithiophene (CPDT) and CPDT derivatives; carbazole and carbazole derivatives; benzotrithiophene and benzotrithiophene derivatives; naphtodithiophene and naphtodithiophene derivatives; and fluorene and fluorene derivatives.

Example 18 includes the device of any of examples 13-17, wherein the electron acceptor material comprise one of a group of electron acceptor materials comprising: fullerene; a fullerene derivative; a polymer; and a small molecule material.

Example 19 includes a method for fabricating an organic semiconductor material, the method comprising: synthesizing an electron donor copolymer having an acceptor-donor-acceptor repeat unit; and combining the electron donor copolymer with an electron acceptor.

Example 20 includes the method of example 19, wherein combining the electron donor copolymer with the electron acceptor further comprises: layering the electron donor copolymer and the electron acceptor to produce a bilayer organic material layer.

Example 21 includes the method of example 19, wherein combining the electron donor copolymer with the electron acceptor further comprises: blending the electron donor copolymer with an electron acceptor into a bulk heterojunction material.

Example 22 includes the method of example 21, further comprising: depositing the bulk heterojunction material on at least one transparent material layer.

Example 23 includes the method of any of examples 19-22. wherein the acceptor moieties of the acceptor-donor-acceptor moiety repeat unit comprise a diketo-pyrrolo-pyrrole (DPP) monomer.

Example 24 includes the method of any of examples 19-23, wherein the donor moiety of the acceptor-donor-acceptor moiety repeat unit comprises one of a group of monomers comprising: ethylenedioxythiophene (EDOT) and EDOT derivatives; propylenedioxythiophene (ProDOT) and ProDOT derivatives; benzodithiophene (BDT) and BDT derivatives; dithieneopyrrole (DTP) and DTP derivatives; dithieneosilole (DTS) and DTS derivatives; cyclopentadithiophene (CPDT) and CPDT derivatives; carbazole and carbazole derivatives; benzotrithiophene and benzotrithiophene derivatives; naphtodithiophene and naphtodithiophene derivatives; and fluorene and fluorene derivatives.

Example 25 includes the method of any of examples 19-24, wherein the electron acceptor material comprise one of a group of electron acceptor materials comprising: fullerene; a fullerene derivative; a polymer; and a small molecule material.

Although specific embodiments have been illustrated and described herein, it will be appreciated by those of ordinary skill in the art that any arrangement, which is calculated to achieve the same purpose, may be substituted for the specific embodiment shown. This application is intended to cover any adaptations or variations of the embodiments described herein. Therefore, it is manifestly intended that embodiments of the present disclosure be limited only by the claims and the equivalents thereof.

What is claimed is:

1. A composition of matter, the composition of matter comprising a copolymer material having an acceptor-donor-acceptor moiety repeat unit.

2. The composition of matter of claim 1, wherein:
the acceptor moieties of the acceptor-donor-acceptor moiety repeat unit comprise a diketo-pyrrolo-pyrrole (DPP) monomer.

3. The composition of matter of claim 2, wherein the donor moiety of the acceptor-donor-acceptor moiety repeat unit comprises one of a group of monomers comprising:
ethylenedioxythiophene (EDOT) and EDOT derivatives;
propylenedioxythiophene (ProDOT) and ProDOT derivatives;
benzodithiophene (BDT) and BDT derivatives;
dithieneopyrrole (DTP) and DTP derivatives;
dithieneosilole (DTS) and DTS derivatives;
cyclopentadithiophene (CPDT) and CPDT derivatives;
carbazole and carbazole derivatives;
benzotrithiophene and benzotrithiophene derivatives;
naphtodithiophene and naphtodithiophene derivatives; and
fluorene and fluorene derivatives.

4. The composition of matter of claim 1, wherein the copolymer material is further blended with an electron acceptor material into a bulk composite to form a bulk heterojunction material, wherein the copolymer material defines an electron donor material within the bulk heterojunction material.

5. The composition of matter of claim 4, wherein the electron acceptor material comprise one of a group of electron acceptor materials comprising:
fullerene;
a fullerene derivative;
a polymer; and
a small molecule material.

6. An organic photovoltaic device, the device comprising:
an organic semiconductor layer comprising a combination of an electron acceptor material with an electron donor copolymer material;
wherein the electron donor copolymer material comprises a repeating sequence of a repeat unit having an acceptor-donor-acceptor moiety pattern.

7. The device of claim 6, wherein the organic semiconductor layer comprises a blend of the electron acceptor material with the electron donor copolymer material forming a bulk heterojunction.

8. The device of claim 6, wherein the organic semiconductor layer comprises a layering of the electron acceptor material and the electron donor copolymer material.

9. The device of claim 6, wherein:
the repeat unit acceptor moieties each comprise a diketo-pyrrolo-pyrrole (DPP) monomer.

10. The device of claim 6, wherein the repeat unit donor moiety comprises one of a group of monomers comprising:
ethylenedioxythiophene (EDOT) and EDOT derivatives;
propylenedioxythiophene (ProDOT) and ProDOT derivatives;
benzodithiophene (BDT) and BDT derivatives;
dithieneopyrrole (DTP) and DTP derivatives;
dithieneosilole (DTS) and DTS derivatives;
cyclopentadithiophene (CPDT) and CPDT derivatives;
carbazole and carbazole derivatives;
benzotrithiophene and benzotrithiophene derivatives;
naphtodithiophene and naphtodithiophene derivatives; and
fluorene and fluorene derivatives.

11. The device of claim 6, wherein the electron acceptor material comprise one of a group of electron acceptor materials comprising:
fullerene;
a fullerene derivative;
a polymer; and
a small molecule material.

12. The device of claim 6, further comprising:
a first contact layer;
a second contact layer;
a hole collection layer;
an electron collection layer; and
an absorber layer that comprises the bulk heterojunction layer, the absorber layer positioned between the hole collection layer and the electron collection layer.

13. An organic photovoltaic device, the device comprising:
a first contact layer;
a second contact layer;
a hole collection layer adjacent to the first transparent contact layer;
an electron collection layer adjacent to the second transparent contact layer; and
an absorber layer positioned between the hole collection layer and the electron collection layer, the absorber layer comprising an electron acceptor material and an electron acceptor polymer material, wherein the electron acceptor polymer material has an acceptor-donor-acceptor repeat unit.

14. The device of claim 13, wherein at least one of the first contact layer or the second contact layer comprises a transparent contact layer.

15. The device of claim 13, wherein both the first contact layer and the second contact layer comprises a transparent conducting layer; and
wherein the absorber layer is at least semi-transparent to light having a wavelength in the visible light spectrum.

16. The device of claim 13, wherein:
the acceptor-donor-acceptor repeat unit comprises a diketo-pyrrolo-pyrrole (DPP) monomer acceptor moiety,

17. The device of claim 13, wherein a donor moiety of the acceptor-donor-acceptor repeat unit comprises one of a group of monomers comprising:
ethylenedioxythiophene (EDOT) and EDOT derivatives;
propylenedioxythiophene (ProDOT) and ProDOT derivatives;
benzodithiophene (BDT) and BDT derivatives;
dithieneopyrrole (DTP) and DTP derivatives;
dithieneosilole (DTS) and DTS derivatives;
cyclopentadithiophene (CPDT) and CPDT derivatives;
carbazole and carbazole derivatives;
benzotrithiophene and benzotrithiophene derivatives;
naphtodithiophene and naphtodithiophene derivatives; and
fluorene and fluorene derivatives.

18. The device of claim 13, wherein the electron acceptor material comprise one of a group of electron acceptor materials comprising:
fullerene;
a fullerene derivative;
a polymer; and
a small molecule material.

19. A method for fabricating an organic semiconductor material, the method comprising:
synthesizing an electron donor copolymer having an acceptor-donor-acceptor repeat unit; and
combining the electron donor copolymer with an electron acceptor.

20. The method of claim 19, wherein combining the electron donor copolymer with the electron acceptor further comprises:
layering the electron donor copolymer and the electron acceptor to produce a bilayer organic material layer.

21. The method of claim 19, wherein combining the electron donor copolymer with the electron acceptor further comprises:
blending the electron donor copolymer with an electron acceptor into a bulk heterojunction material.

22. The method of claim 21, further comprising:
depositing the bulk heterojunction material on at least one transparent material layer.

23. The method of claim 19, wherein the acceptor moieties of the acceptor-donor-acceptor moiety repeat unit comprise a diketo-pyrrolo-pyrrole (DPP) monomer.

24. The method of claim 19, wherein the donor moiety of the acceptor-donor-acceptor moiety repeat unit comprises one of a group of monomers comprising:
ethylenedioxythiophene (EDOT) and EDOT derivatives;
propylenedioxythiophene (ProDOT) and ProDOT derivatives;
benzodithiophene (BDT) and BDT derivatives;
dithieneopyrrole (DTP) and DTP derivatives;
dithieneosilole (DTS) and DTS derivatives;
cyclopentadithiophene (CPDT) and CPDT derivatives;
carbazole and carbazole derivatives;
benzotrithiophene and benzotrithiophene derivatives;
naphtodithiophene and naphtodithiophene derivatives; and
fluorene and fluorene derivatives.

25. The method of claim 19, wherein the electron acceptor material comprise one of a group of electron acceptor materials comprising:
fullerene;
a fullerene derivative;
a polymer; and
a small molecule material.
